(19) United States
(12) Patent Application Publication
(10) Pub. No.: US 2011/0303285 A1
(43) Pub. Date: Dec. 15, 2011

(54) SOLAR MODULE SUPPORT AND SOLAR CELL MODULE

(76) Inventors: Kuan-Wen Tung, Taoyuan County (TW); Chien-Chun Chen, Hsinchu City (TW)

(21) Appl. No.: 12/814,508

(22) Filed: Jun. 14, 2010

(51) Int. Cl. H01L 31/00; F16M 13/00

(52) U.S. Cl. 136/259; 248/314

(57) ABSTRACT

A solar module support with at least one switching circuit is provided. When a solar cell module is plugged in a solar module socket of the solar module support, the switching circuit is turned off. When the solar cell module is pulled out from the solar module socket, the switching circuit is turned on. Current originally flows through the solar cell module can flows through the switching circuit alternatively, when the solar cell module is detached from the solar module support.

### BACKGROUND OF THE INVENTION

1. Field of the Invention

The invention relates to a solar module support having a switching circuit controlled by a solar cell module.

2. Description of the Prior Art

Solar cells, also referred to as “photovoltaic cells, ” are well known devices for converting solar radiation to electrical energy. They may be fabricated on a semiconductor wafer using semiconductor processing technology. Generally speaking, a solar cell may be fabricated by forming p-doped and n-doped regions in a silicon substrate. Solar radiation impinging on the solar cell creates electrons and holes that migrate to the p-doped and n-doped regions, thereby creating voltage differentials between the doped regions.

In order to construct a photovoltaic power generation system in which a high current and high voltage is required, a plurality of solar cells are in serial or parallel connection to obtain the desired output current and output voltage.

The solar cell is susceptible to corrosion and easily broken by a shock from an external source. Therefore, the connected solar cells are sandwiched and laminated between a front sheet and a back sheet to form a solar cell module. An adhesive layer is disposed between the front sheet and the back sheet and encapsulated the solar cells. The adhesive layer is for adhering the front sheet to the back sheet. A plurality of solar cell module can electrically connect to each other to form a solar cell array.

However, after a period time of usage, the solar cell in the solar cell module may still be damaged by outdoor condition. Since solar cells in the solar module are usually in serial connection, when one of the solar cells does not function, the entire string of the solar cells are not workable. Therefore, a new solar cell must be inserted to replace the damaged one to maintain the serial connection, or the entire solar cell module including the damaged solar cell and the workable solar cell needs to be replaced, which is a waste. The repair methods require removing the front sheet. Subsequently, the defective solar cell is removed from the back sheet. Then, a new solar cell is inserted into the repair site. Such replacement of solar cells may damage the back sheet and the adjoining solar cells, and requires high expenditures.

### SUMMARY OF THE INVENTION

Therefore, it is an object of the present invention to provide a solar cell module which can be replaced with lower expenditures and a solar module support which keeps the serial solar cells working even one of the solar cells in the string is pulled out from the solar module support.

According to a preferred embodiment of the present invention, a solar module support includes: a substrate, a first switching circuit configured in the substrate and a first solar module socket embedded in the substrate for fixing a first solar cell module, wherein when the first solar cell module is engaged with the first solar module socket, the first switching circuit is turned off and a first current passes through the first solar cell module, and when the first solar cell module detaches from the first solar module socket, a second current passes through the first switching circuit.

The switching circuit serves as a bypass when the solar cell module is pulled out from the solar module support. Therefore, the serial connection of the solar cell array can still function well.

Furthermore, the arrangement of the solar cell modules on the solar module support can be customized to form a desired pattern. For example, a symbol of a company can be pieced together by placing solar cell modules in the designated sockets.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram depicting a solar module support according to a preferred embodiment of the present invention.

FIG. 2A shows a top view of the structure of a solar cell module according to a preferred embodiment of the present invention schematically.

FIG. 2B shows a sectional view of the solar cell module taken along line AA′ in FIG. 2A.

FIG. 3 is a schematic diagram depicting a turned off switching circuit when the solar cell module is engaged with the solar module support.

FIG. 4 is a schematic diagram of FIG. 1 depicting a turned on switching circuit when the solar cell module is detached from the solar module support.

### DETAILED DESCRIPTION

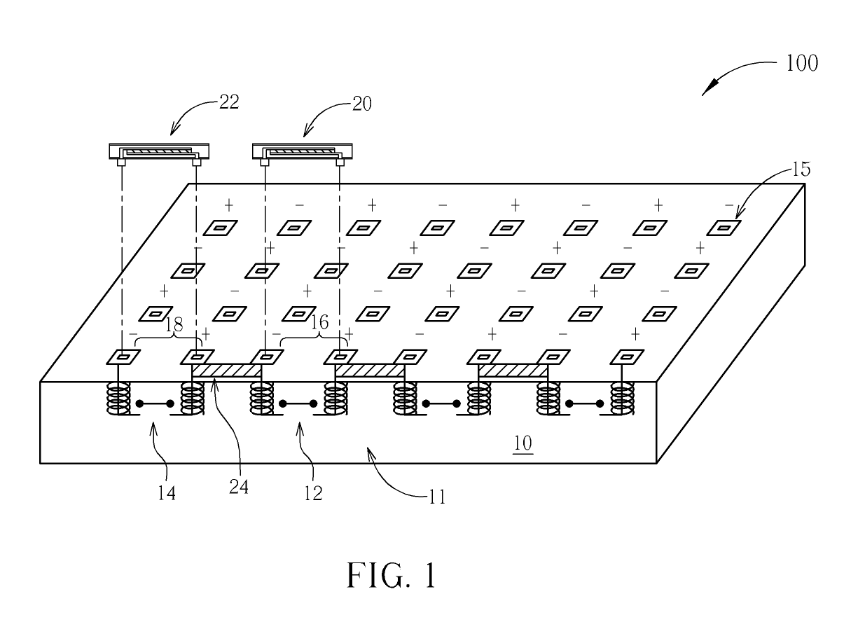

FIG. 1 is a schematic diagram depicting a solar module support according to a preferred embodiment of the present invention. As shown in FIG. 1, a solar module support 100 includes a substrate 10. The substrate 10 may be a case having a cavity within. A plurality of switching circuits 11 such as a first switching circuit 12 and a second switching circuit 14 are configured inside the substrate 10. The top surface or the bottom surface of the substrate 10 may be disposed numerous springs (not shown) and posts (not shown) for routing the switching circuits. It is noteworthy that the solar module support 100 further includes numerous solar module sockets 15, such as a first and a second solar module sockets 16, 18 embedded in the top surface of the substrate 10. The first and the second solar module sockets 16, 18 are for fixing or installing a first solar cell module 20 and a second solar cell module 22, respectively. Other solar module sockets are capable of fixing or installing other solar cell modules. The first switching circuit 12 may be composed of resilient members and wire segments. The second switching circuit 14 may have the same configuration as the first switching circuit 12. An interconnection circuit 24 is configured inside the substrate 10 and electrically connects the adjacent switching circuits or the adjacent solar modules. The structures of the first and second switching circuits 12, 14 are described in greater detail later, a brief description is provided now to aid in the understanding of the structure solar module support 100.

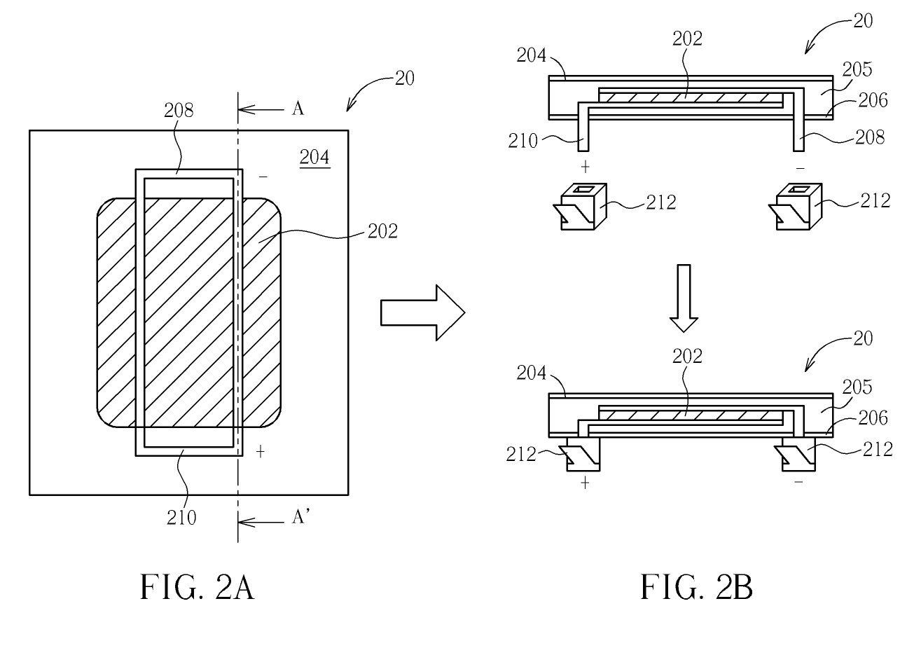

FIG. 2A shows a top view of the structure of a solar cell module according to a preferred embodiment of the present invention schematically. FIG. 2B shows a sectional view of the solar cell module taken along line AA′ in FIG. 2A.

Please refer to both FIG. 2A and FIG. 2B, the first solar cell module 20 includes at least one solar cell 202. A front sheet 204 and a back sheet 206 sandwich the solar cell 202. An adhesive layer 205 encapsulates the solar cell 202. The adhesive layer 205 can be ethylene vinyl acetate (EVA) for adhere the solar cell 202, the front sheet 204, and the back sheet 206. Although only one solar cell 202 is disposed in the first solar cell module 20, however, more than one solar cell can be packaged together to become the first solar cell module 20. An anode wire 208 and a cathode wire 210, which serve as electrodes, extend from the surface of the solar cell module 20 and penetrate the adhesive layer 205, and the back sheet 206. Alternatively, the anode wire 208 and the cathode wire 210 can extend from the side surface of the solar cell module 20. Then, the anode wire 208 and the cathode wire 210 can be bent toward the back sheet 206. After that, the anode wire 208 and the cathode wire 210 are inserted into plugs 212 respectively. The plugs 212 are advantageously substantially perpendicular to the back sheet 206. Furthermore, the plug 212 with the anode wire 208 inside may have different features from the other plug 212 with cathode wire 210 inside. For instance, the plug 212 with the anode wire 208 inside may be blue color, and the plug 212 with cathode wire 210 inside may be green color. The plugs 212 may be any plugs which can fix the solar cell module 20 tightly on the solar module support. For example, the plugs may be analogous to phone plugs, Ethernet cable plugs or other types of plugs, but not limited thereto. The free ends of the plugs 212 can expose the end point of the anode wire 206 and the end point of the cathode wire 210. Although only the structure of first solar cell module 20 is described, the aforesaid second solar cell module 22, and other solar cell module utilizing in the present invention have structure that is identical with the first solar cell module 20.

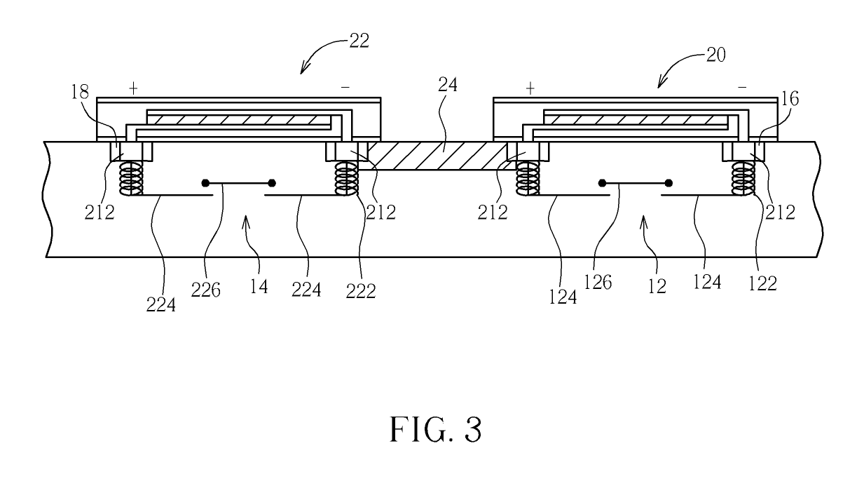

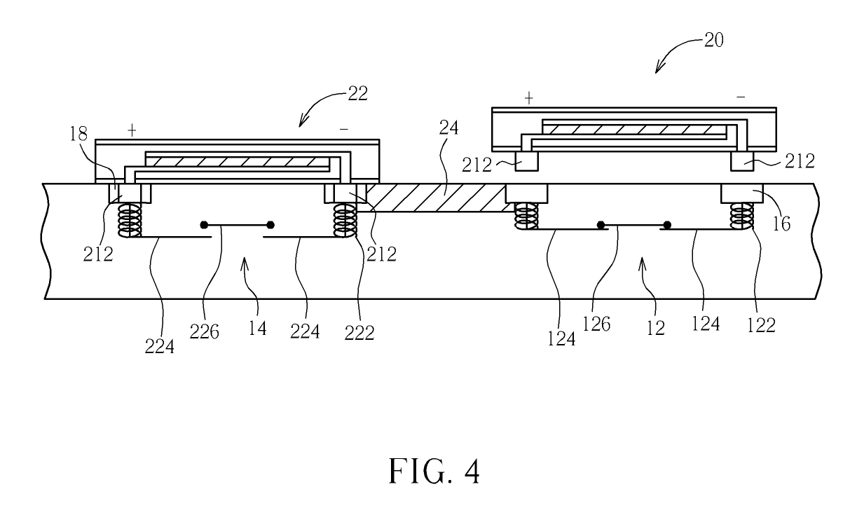

FIG. 3 is a schematic diagram depicting a turned off switching circuit when the solar cell module is engaged with the solar module support. FIG. 4 is a schematic diagram of FIG. 1 depicting a turned on switching circuit when the solar cell module is detached from the solar module support. For the sake of simplicity, only two switching circuits are shown in FIG. 3 and FIG. 4. However, it is understood that all the switching circuits 11 on the solar module support 100 can be operated in the same way.

Please refer to FIGS. 1-3, the first solar cell module 20 is engaged with the substrate 10, and the second solar cell module 22 is also engaged with the substrate 10. By plugging the plugs 212 on the first solar cell module 20 into the first solar module socket 16, the plugs 212 interlock with the first solar module socket 16. More particularly, the first solar module socket 16 has two individual recesses. Each individual recess is corresponding to an anode and a cathode respectively. The plug 212 with anode wire 208 inside should be plugged into the anode recess, and the plug 212 with cathode wire 210 inside should be plugged into the cathode recess.

When the first solar cell module 20 is engaged with the substrate 10, the first switching circuit 12 is turned off, and no current can flow through the first switching circuit 12. The first switching circuit 12 includes two L-shaped wire segments 124, two resilient members 122 and a bridging wire segment 126. The second switching circuit 14 includes two L-shaped wire segments 224, two resilient members 222 and a bridging wire segment 226.

According to a preferred embodiment of the present invention, when the first solar cell module 20 is plugged into the first solar module socket 16, the resilient members 122 of the first switching circuit 12 is pressed down, and two L-shaped wire segments 124 are separate from a bridging wire segment 126. The first switching circuit 12 is therefore turned off. At this point, the first and the second solar cell modules 20, 22 are in serial connection. The current provided by the second solar cell module 22 flows through the L-shaped wire segments 224, interconnection circuit 24, the L-shaped wire segment 124 to the cathode wire 210 of the first solar cell module 20. The interconnection circuit 24 connects to the L-shaped wire segment 224 of the second switching circuit 14 to the L-shaped wire segment 124 of the first switching circuit 12.

As shown in FIGS. 1-2 and 4, the first solar cell module 20 is detached from the substrate 10, and the second solar cell module 22 is still engaged with the substrate 10. When the first solar cell module 20 is detached from the substrate 10, the first switching circuit 12 is turned on, and a current flow from the second solar cell module 22 can flow through the L-shaped wire segment 224, the interconnection circuit 24 to the first switching circuit 12. When the first solar cell module 20 is pulled out from the first solar module socket 16, the resilient members 122 of the first switching circuit 12 springs back to their original positions, and the L-shaped wire segments 124 reconnect to the bridging wire segment 126.

Although in FIG. 3 and FIG. 4 merely describe the plug in and plug out of the first solar cell module 20 associated with the first switching circuit 12. However, the second switching circuit 14 is controlled in the same way as the first switching circuit 12. That is, when the second solar cell module 22 is plugged in, the second switching circuit 14 is turned off and when second solar cell module 22 is plugged out, the second switching circuit 14 is turned on. Furthermore, each of the solar module sockets 15 on the solar module support 100 can be plugged in with one solar cell module to supply greater voltage.

The solar cell module of the present invention offers an easy way to replace a defective solar cell module. Only by plugging in and out, the solar cell module can be engaged with the solar module support or detached from the solar module support. Furthermore, when the solar cell module is pulled out, the switching circuit corresponding to it turns on to maintain the serial circuit. Even there is no new solar cell module can plug in to replace the broken one, the serial circuit can still functions as long as the broken solar cell module is plugged out. Moreover, since there is merely a solar cell in one solar cell module, when the solar cell is damaged, the entire solar cell module can be replaced without peeling off the front sheet. Therefore, the expenditures of replacement of solar cell module are saved. Furthermore, the arrangement of the solar cell modules on the solar module support can be customized to form a desired pattern. For example, a symbol of a company can be pieced together by placing solar cell modules in their designated sockets.

Those skilled in the art will readily observe that numerous modifications and alterations of the device and method may be made while retaining the teachings of the invention.

What is claimed is:

1. A solar module support, comprising:
a substrate;
a first switching circuit configured in the substrate; and
a first solar module socket disposed in the substrate for installing a first solar cell module, wherein when the first solar cell module is engaged with the first solar module socket, a first current passes through the first solar cell module, and when the first solar cell module detaches from the first solar module socket, a second current passes through the first switching circuit.

2. The solar module support of claim 1, further comprising a second switching circuit configured in the substrate, a second solar module socket disposed in the substrate for installing a second solar cell module.

3. The solar module support of claim 2, wherein when the first solar cell module is engaged with the first solar module socket, the first current passing through the first solar cell module is provided by the second solar cell module and the first solar cell module.

4. The solar module support of claim 2, wherein when the first solar cell module detaches from the first solar module socket, the second current passing through the first switching circuit is provided by the second solar cell module.

5. The solar module support of claim 2, further comprising an interconnection circuit configured on the substrate and the interconnection circuit electrically connects the first switching circuit with the second solar cell module.

6. The solar module support of claim 2, further comprising an interconnection circuit configured on the substrate and the interconnection circuit electrically connects the first solar cell module with the second solar cell module.

7. The solar module support of claim 1, wherein the first solar cell module further comprises two plugs, and the plugs are capable of plugging into the first solar module socket so as to interlock the first solar cell module on the substrate.

8. The solar module support of claim 1, wherein when the first solar cell module is engaged with the first solar module socket, the first switching circuit is turned off, and when the first solar cell module is detached from the first solar module socket, the first switching circuit is turned on.

9. A solar cell module, comprising:
a back sheet;
a front sheet disposed on the back sheet;
at least one solar cell disposed between the front sheet and the back sheet;
an adhesive layer encapsulating the at least one solar cell;
an anode wire penetrating the adhesive layer and the back sheet; and
a cathode wire penetrating the adhesive layer and the back sheet.

10. The solar cell module of claim 9, further comprising two plugs, the anode wire is inserted into one plug and the cathode wire is inserted into the other plug.

11. The solar module support of claim 10, the plugs are capable of being fixed on a solar module support.

12. The solar module support of claim 11, wherein the solar module support comprises:
a substrate;
a switching circuit configured in the substrate; and
a solar module socket disposed in the substrate for engaging the two plugs of the solar cell module.
